(19) United States
(12) Patent Application Publication
(10) Pub. No.: US 2026/0037012 A1
(43) Pub. Date: Feb. 5, 2026

(54) LOW DROPOUT REGULATOR

(71) Applicant: Winbond Electronics Corp., Taichung City (TW)

(72) Inventor: Chih-Feng Lin, Hsinchu County (TW)

(73) Assignee: Winbond Electronics Corp., Taichung City (TW)

(21) Appl. No.: 19/246,744

(22) Filed: Jun. 24, 2025

(30) Foreign Application Priority Data
Aug. 2, 2024 (TW) 113128964

(51) Int. Cl. G05F 1/56; H03K 19/20

(52) U.S. Cl. CPC G05F 1/56; H03K 19/20

(57) ABSTRACT

A low dropout regulator including an amplifier circuit, an equalizer circuit, a compensation capacitor, a discharge circuit and a detection circuit. The amplifier circuit operates between a first power supply voltage and a second power supply voltage and includes a differential input pair having a first stage input circuit and a second stage input circuit. The amplifier circuit is configured to generate an output voltage according to an input voltage and a reference voltage. The equalizer circuit is coupled between two intermediate nodes where the first stage circuit and the second stage input circuit are stacked, and is configured to short circuit as controlled by a control signal. The discharge circuit is configured to pull down a common mode voltage of a common terminal of the differential input pair as controlled by the control signal. The detection circuit is configured to generate the control signal according to a node voltage of one of the two intermediate nodes.

### CROSS-REFERENCE TO RELATED APPLICATION

This application claims the priority benefit of Taiwan application serial no. 113128964, filed on Aug. 2, 2024. The entirety of the above-mentioned patent application is hereby incorporated by reference herein and made a part of this specification.

### BACKGROUND

### Technical Field

The present invention relates to a voltage regulator, and particularly relates to a low dropout regulator (LDO).

### Related Art

As the continuous evolution of dynamic random access memory (DRAM) specifications, the input voltage is becoming lower, but the operating frequency is becoming faster. Therefore, the response speed and output capability of the low dropout regulator are increasingly important. Currently, to improve the stability of the low dropout regulator, a compensation capacitor may be added to the low dropout regulator, thereby improving frequency response. However, during the activation process of the low dropout regulator, the compensation capacitor needs to be discharged, thus requiring a longer settling time to stabilize internal voltages, resulting in a decrease in activation speed.

### SUMMARY

The present invention provides a low dropout regulator that can accelerate the discharge speed of the compensation capacitor.

The low dropout regulator of the present invention includes an amplifier circuit, an equalizer circuit, a compensation capacitor, a discharge circuit and a detection circuit. The amplifier circuit operates between a first power supply voltage and a second power supply voltage and includes a differential input pair having a first stage input circuit and a second stage input circuit. The amplifier circuit is configured to receive an input voltage and a reference voltage through the first stage input circuit and the second stage input circuit, and generate an output voltage according to the input voltage and the reference voltage. The equalizer circuit is coupled between two intermediate nodes where the first stage input circuit and the second stage input circuit are stacked, and is configured to short circuit as controlled by a control signal. The compensation capacitor is coupled to one of the two intermediate nodes. The discharge circuit is coupled between the common terminal of the differential input pair and the second power supply voltage, and is configured to pull down a common mode voltage of the common terminal as controlled by the control signal. The detection circuit is coupled to the amplifier circuit, the equalizer circuit, and the discharge circuit, and is configured to generate the control signal according to a node voltage of one of the two intermediate nodes.

Based on the above, the low dropout regulator of the present invention may actively pull down the common mode voltage of the common terminal of the differential input pair to accelerate the discharge speed of the compensation capacitor. As a result, the time spent when activating the low dropout regulator can be significantly reduced, the activation speed can be improved, and the user may use the compensation capacitor with larger capacity, thereby obtaining better stability.

To make the above features and advantages of the present invention more clearly understandable, embodiments are provided below with detailed explanations in conjunction with the accompanying FIG.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a block diagram of a low dropout regulator according to an embodiment of the present invention.

FIG. 2 illustrates a circuit diagram of the low dropout regulator of the embodiment in FIG. 1.

FIG. 3A and FIG. 3B illustrate circuit diagrams of a discharge circuit according to an embodiment of the present invention.

FIG. 4 illustrates a circuit diagram of a detection circuit according to an embodiment of the present invention.

FIG. 5 illustrates a signal waveform diagram of a detection circuit according to an embodiment of the present invention.

### DESCRIPTION OF THE EMBODIMENTS

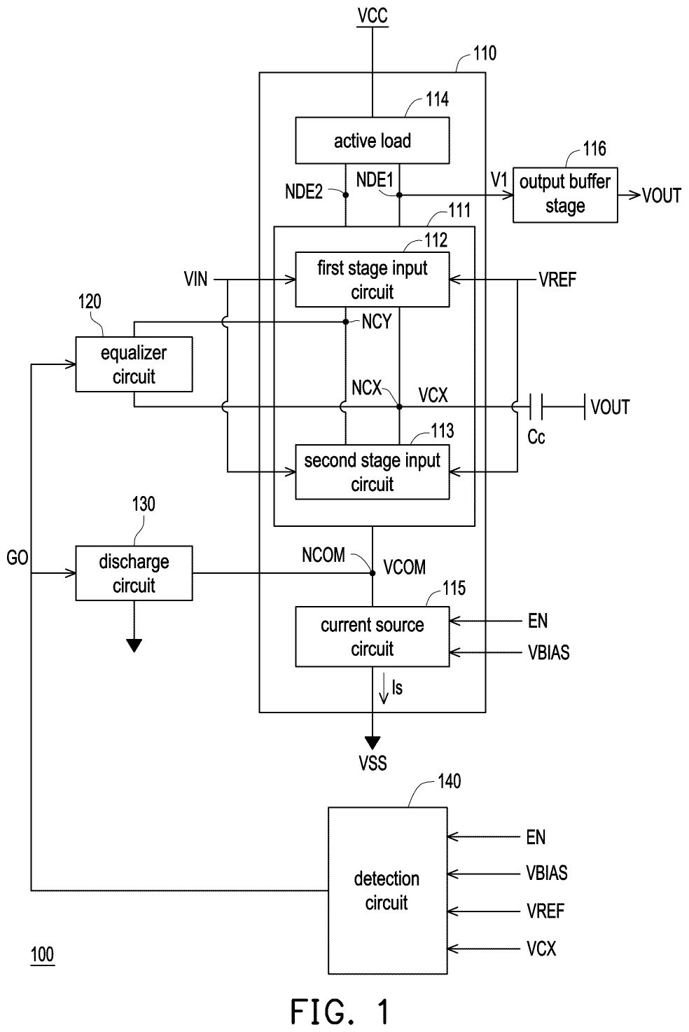

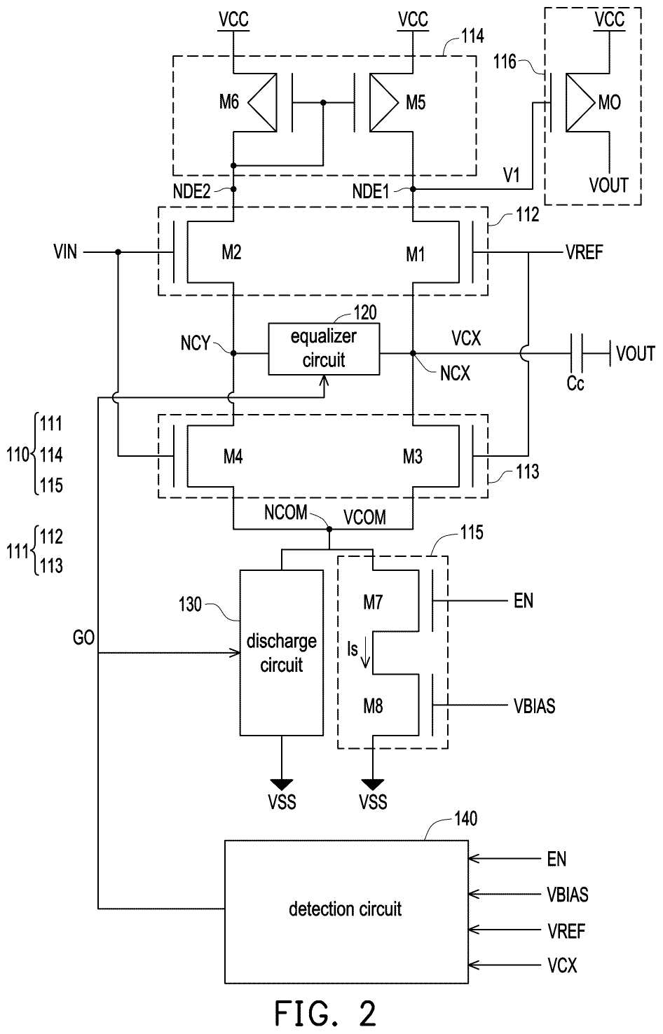

Please refer to both FIG. 1 and FIG. 2, the low dropout regulator 100 of this embodiment includes an amplifier circuit 110, an equalizer circuit 120, a compensation capacitor Cc, a discharge circuit 130, and a detection circuit 140. The amplifier circuit 110 operates between a first power supply voltage VCC and a second power supply voltage VSS. The amplifier circuit 110 includes a differential input pair 111. The differential input pair 111 has a first stage input circuit 112 and a second stage input circuit 113. The amplifier circuit 110 is configured to receive an input voltage VIN and a reference voltage VREF through the first stage input circuit 112 and the second stage input circuit 113. The first power supply voltage VCC is greater than the second power supply voltage VSS.

The amplifier circuit 110 may generate an output voltage VOUT according to the input voltage VIN and the reference voltage VREF. Specifically, the amplifier circuit 110 may adjust the input voltage VIN according to the reference voltage VREF to convert it into the output voltage VOUT.

In structure, the first stage input circuit 112 includes a first transistor M1 and a second transistor M2. The first terminal of the first transistor M1 is coupled to a first differential terminal NDE1 of the differential input pair 111, the second terminal of the first transistor M1 is coupled to a first intermediate node NCX, and the control terminal of the first transistor M1 receives the reference voltage VREF. The first terminal of the second transistor M2 is coupled to a second differential terminal NDE2 of the differential input pair 111, the second terminal of the second transistor M2 is coupled to a second intermediate node NCY, and the control terminal of the second transistor M2 receives the input voltage VIN. The second stage input circuit 113 includes a third transistor M3 and a fourth transistor M4. The first terminal of the third transistor M3 is coupled to the first intermediate node NCX, the second terminal of the third transistor M3 is coupled to a common terminal NCOM of the differential input pair 111, and the control terminal of the third transistor M3 receives the reference voltage VREF. The first terminal of the fourth transistor M4 is coupled to the second intermediate node NCY, the second terminal of the fourth transistor M4 is coupled to the common terminal NCOM of the differential input pair 111, and the control terminal of the fourth transistor M4 receives the input voltage VIN. The first to fourth transistors M1-M4 may be implemented, for example, as N-type Metal-Oxide-Semiconductor Field-Effect Transistors (NMOSFET).

In FIG. 1, the amplifier circuit 110 further includes an active load 114, a current source circuit 115, and an output buffer stage 116. The active load 114 is coupled between the first power supply voltage VCC and the two differential terminals (the first differential terminal NDE1 and the second differential terminal NDE2) of the differential input pair 111. The active load 114 is configured to output a control voltage V1 from the first differential terminal NDE1 to the output buffer stage 116, and control the output buffer stage 116 to generate the output voltage VOUT.

The current source circuit 115 is coupled between the common terminal NCOM of the differential input pair 111 and the second power supply voltage VSS. The current source circuit 115 is configured to receive an enable signal EN, and in response to the enable signal EN, begin to adjust a generated operating current Is according to a bias voltage VBIAS. The enable signal EN comes from, for example, a memory controller or any signal generator. Specifically, when the enable signal EN converts to the first logic level, the current source circuit 115 may adjust the magnitude of the operating current Is according to the bias voltage VBIAS.

In structure, the active load 114 includes a fifth transistor M5 and a sixth transistor M6. The first terminal of the fifth transistor M5 receives the first power supply voltage VCC, the second terminal of the fifth transistor M5 is coupled to the first differential terminal NDE1, and the control terminal of the fifth transistor M5 is coupled to the second differential terminal NDE2. The first terminal of the sixth transistor M6 receives the first power supply voltage VCC, the second terminal of the sixth transistor M6 is coupled to the second differential terminal NDE2, and the control terminal of the sixth transistor M6 is coupled to the control terminal of the fifth transistor M5.

The current source circuit 115 includes a seventh transistor M7 and an eighth transistor M8. The first terminal of the seventh transistor M7 is coupled to the common terminal NCOM, and the control terminal of the seventh transistor M7 receives the enable signal EN. The first terminal of the eighth transistor M8 is coupled to the second terminal of the seventh transistor M7, the second terminal of the eighth transistor M8 receives the second power supply voltage VSS, and the control terminal of the eighth transistor M8 receives the bias voltage VBIAS. The output buffer stage 116 includes an output transistor MO. The first terminal of the output transistor MO receives the first power supply voltage VCC, the second terminal of the output transistor MO generates the output voltage VOUT, and the control terminal of the output transistor MO receives the control voltage V1. The fifth and sixth transistors M5, M6 and the output transistor MO may be implemented, for example, as P-type Metal-Oxide-Semiconductor Field-Effect Transistors (PMOSFET). The seventh and eighth transistors M7, M8 may be implemented, for example, as N-type Metal-Oxide-Semiconductor Field-Effect Transistors.

The equalizer circuit 120 is coupled between two intermediate nodes (the first intermediate node NCX and the second intermediate node NCY) where the first stage input circuit 112 and the second stage input circuit 113 are stacked. The equalizer circuit 120 may be implemented, for example, as an N-type Metal-Oxide-Semiconductor Field-Effect Transistor, a P-type Metal-Oxide-Semiconductor Field-Effect Transistor, a combination of these transistors, or other known switch circuits.

The equalizer circuit 120 is configured to short circuit as controlled by the control signal GO. Specifically, when the control signal GO is in the first logic level, the equalizer circuit 120 may make the path between the first intermediate node NCX and the second intermediate node NCY conductive. When the control signal GO is in the second logic level, the equalizer circuit 120 may disconnect the path between the first intermediate node NCX and the second intermediate node NCY.

The compensation capacitor Cc is coupled to the first intermediate node NCX. Specifically, the first terminal of the compensation capacitor Cc is coupled to the first intermediate node NCX, and the second terminal of the compensation capacitor Cc receives the output voltage VOUT.

The discharge circuit 130 is coupled between the common terminal NCOM of the differential input pair 111 and the second power supply voltage VSS, in parallel with the current source circuit 115. The discharge circuit 130 is configured to pull down the common mode voltage VCOM of the common terminal NCOM as controlled by the control signal GO. Specifically, when the control signal GO is in the first logic level, the discharge circuit 130 may be turned on to pull down the common mode voltage VCOM. When the control signal GO is in the second logic level, the discharge circuit 130 may be turned off.

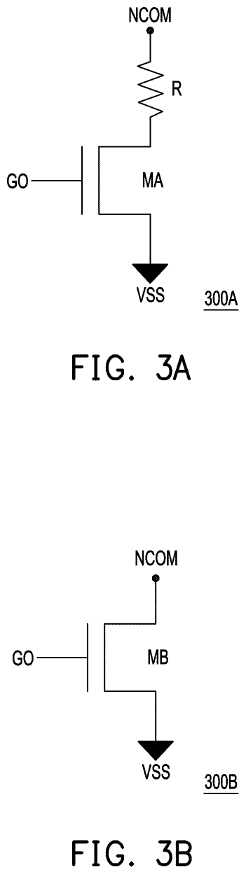

The following examples illustrate the detailed structure of the discharge circuit. In one embodiment, as shown in FIG. 3A, the discharge circuit 300A may be constructed by a resistor R and a transistor MA. One terminal of the resistor R is coupled to the common terminal NCOM. The first terminal of the transistor MA is coupled to the other terminal of the resistor R, the second terminal of the transistor MA receives the second power supply voltage VSS, and the control terminal of the transistor MA receives the control signal GO. In another embodiment, as shown in FIG. 3B, the discharge circuit 300B may be constructed by a transistor MB. The first terminal of the transistor MB is coupled to the common terminal NCOM, the second terminal of the transistor MB receives the second power supply voltage VSS, and the control terminal of the transistor MB receives the control signal GO. The transistors MA and MB may be implemented, for example, as N-type Metal-Oxide-Semiconductor Field-Effect Transistors.

The detection circuit 140 is coupled to the amplifier circuit 110, the equalizer circuit 120, and the discharge circuit 130. The detection circuit 140 is configured to generate the control signal GO provided to the equalizer circuit 120 and the discharge circuit 130 according to the node voltage VCX of the first intermediate node NCX.

In detailed operation, the detection circuit 140 receives the enable signal EN, the bias voltage VBIAS, the reference voltage VREF, and the node voltage VCX. The detection circuit 140 may converts the control signal GO from the second logic level to the first logic level in response to the enable signal EN, and determine the duration of the activation time Tstr during which the control signal GO is in the first logic level according to the node voltage VCX.

Specifically, first, when the enable signal EN is converted to the first logic level, the detection circuit 140 may convert the control signal GO from the second logic level to the first logic level. At the same time, the detection circuit 140 may begin to generate a bias current IBIAS according to the bias voltage VBIAS, and generate a node current ICX according to the reference voltage VREF and the node voltage VCX. Furthermore, the detection circuit 140 may compare the node current ICX with the bias current IBIAS.

Since during the period when the control signal GO is converted to the first logic level, the equalizer circuit 120 makes the path between the first intermediate node NCX and the second intermediate node NCY conductive, and the discharge circuit 130 pulls down the common mode voltage VCOM, the discharge speed of the compensation capacitor Cc will be accelerated, and the node voltage VCX will also rapidly decrease. At this time, the node current ICX will rise as the node voltage VCX decreases. When the node current ICX rises to be greater than the bias current IBIAS, indicating that the node voltage VCX has decreased to the expected voltage, the detection circuit 140 may convert the control signal GO from the first logic level to the second logic level. Thereby, the detection circuit 140 may determine the activation time Tstr during which the control signal GO is in the first logic level based on the comparison result between the node current ICX and the bias current IBIAS, and after the activation time Tstr, cause the equalizer circuit 120 to disconnect the path between the first intermediate node NCX and the second intermediate node NCY and cause the discharge circuit 130 to stop pulling down the common mode voltage VCOM, thus allowing the low dropout regulator 100 of this embodiment to recover to its original operation. As a result, the low dropout regulator 100 of this embodiment can accelerate the discharge speed of the compensation capacitor Cc when the voltages of the first intermediate node NCX and the second intermediate node NCY are matched (balanced).

In practical applications, the first power supply voltage VCC may be 3.3 volts or 5 volts, the second power supply voltage VSS may be 0 volts, the reference voltage VREF may be 1 volt, and the bias voltage VBIAS may be 0.5 volts, but the present invention is not limited thereto. Furthermore, the first logic level mentioned above is logic 1 (for example, 3.3 volts or 5 volts), and the second logic level mentioned above is logic 0 (for example, 0 volts), but the present invention is not limited thereto. In other embodiments, according to actual requirements, the first logic level may also be logic 0, and the second logic level may also be logic 1.

Incidentally, the first power supply voltage VCC, the second power supply voltage VSS, the reference voltage VREF, the bias voltage VBIAS, and the enable signal EN used by the low dropout regulator 100 of the present invention are all existing voltages or signals within the memory device, and do not need to be generated additionally.

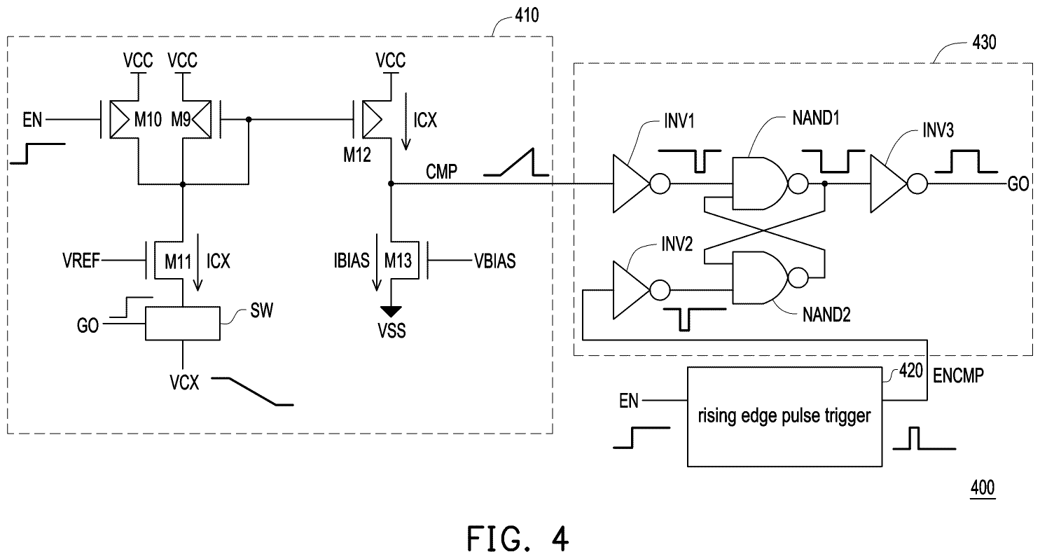

The following examples illustrate the detailed structure of the detection circuit. Referring to FIG. 4, the detection circuit 400 includes a current comparison circuit 410, a rising edge pulse trigger 420, and a latch circuit 430. The current comparison circuit 410 is configured to receive the bias voltage VBIAS, the reference voltage VREF, the node voltage VCX, and the enable signal EN. The current comparison circuit 410 may generate the bias current IBIAS according to the bias voltage VBIAS in response to the control signal GO and the enable signal EN, and generate the node current ICX according to the reference voltage VREF and the node voltage VCX, and compare the node current ICX with the bias current IBIAS to generate a comparison voltage CMP.

The rising edge pulse trigger 420 is configured to receive the enable signal EN, and output a positive pulse signal ENCMP in response to the enable signal EN. Specifically, when the enable signal EN converts to the first logic level, the rising edge pulse trigger 420 may output the positive pulse signal ENCMP.

The latch circuit 430 is coupled to the current comparison circuit 410 and the rising edge pulse trigger 420. The latch circuit 430 is configured to receive the comparison voltage CMP and the positive pulse signal ENCMP, and adjust the control signal GO according to the comparison voltage CMP and the positive pulse signal ENCMP. Specifically, when receiving the positive pulse signal ENCMP, the latch circuit 430 may convert the control signal GO from the second logic level to the first logic level. When the comparison voltage CMP rises to a voltage corresponding to logic 1, the latch circuit 430 may convert the control signal GO from the first logic level to the second logic level.

In structure, the current comparison circuit 410 includes a ninth transistor M9, a tenth transistor M10, an eleventh transistor M11, a switch circuit SW, a twelfth transistor M12, and a thirteenth transistor M13. The first terminal of the ninth transistor M9 receives the first power supply voltage VCC, and the control terminal of the ninth transistor M9 is mutually coupled to the second terminal. The first terminal of the tenth transistor M10 receives the first power supply voltage VCC, the second terminal of the tenth transistor M10 is coupled to the second terminal of the ninth transistor M9, and the control terminal of the tenth transistor M10 receives the enable signal EN. The first terminal of the eleventh transistor M11 is coupled to the second terminal of the tenth transistor M10, and the control terminal of the eleventh transistor M11 receives the reference voltage VREF. The first terminal of the switch circuit SW is coupled to the second terminal of the eleventh transistor M11, the second terminal of the switch circuit SW receives the node voltage VCX, and the control terminal of the switch circuit SW receives the control signal GO to be turned on or turned off as controlled by the control signal GO. The first terminal of the twelfth transistor M12 receives the first power supply voltage VCC, the second terminal of the twelfth transistor M12 is used to generate the comparison voltage CMP, and the control terminal of the twelfth transistor M12 is coupled to the control terminal of the ninth transistor M9. The first terminal of the thirteenth transistor M13 is coupled to the second terminal of the twelfth transistor M12, the second terminal of the thirteenth transistor M13 receives the second power supply voltage VSS, and the control terminal of the thirteenth transistor M13 receives the bias voltage VBIOS.

The latch circuit 430 includes a first inverter INV1, a second inverter INV2, a first NAND gate NAND1, a second NAND gate NAND2, and a third inverter INV3. The input terminal of the first inverter INV1 receives the comparison voltage CMP. The input terminal of the second inverter INV2 receives the positive pulse signal ENCMP. The first input terminal of the first NAND gate NAND1 is coupled to the output terminal of the first inverter INV1. The first input terminal of the second NAND gate NAND2 is coupled to the output terminal of the first NAND gate NAND1, the second input terminal of the second NAND gate NAND2 is coupled to the output terminal of the second inverter INV2, and the output terminal of the second NAND gate NAND2 is coupled to the second input terminal of the first NAND gate NAND1. The input terminal of the third inverter INV3 is coupled to the output terminal of the first NAND gate NAND1, and the output terminal of the third inverter INV3 is used to generate the control signal GO.

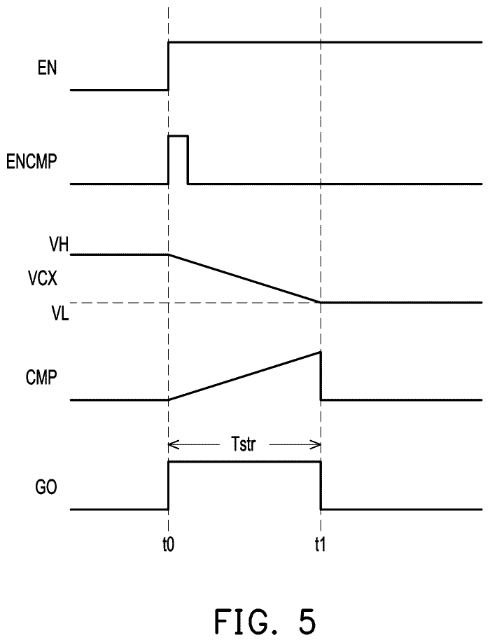

FIG. 5 illustrates the timing waveforms of the enable signal EN, the positive pulse signal ENCMP, the node voltage VCX, the comparison voltage CMP, and the control signal GO. The following describes the operation method of the detection circuit 400, please refer to FIG. 4 and FIG. 5 simultaneously. When the device is activated (i.e., at time point t0), the enable signal EN is converted to the first logic level. At this time, the rising edge pulse trigger 420 outputs the positive pulse signal ENCMP to the second inverter INV2 in the latch circuit 430, causing the second inverter INV2 to output a negative pulse to the second input terminal of the second NAND gate NAND2. Thus, through the circuit structure constructed by the first NAND gate NAND1 and the second NAND gate NAND2, the signal output from the output terminal of the first NAND gate NAND1 is converted to the second logic level, causing the control signal GO generated from the output terminal of the third inverter INV3 to be converted to the first logic level. Meanwhile, the node voltage VCX is in a high voltage value VH.

At time point t0, since both the enable signal EN and the control signal GO are converted to the first logic level, the tenth transistor M10 in the current comparison circuit 410 and the switch circuit SW are turned on as controlled by the enable signal EN and the control signal GO respectively, thereby beginning to generate the bias current IBIAS flowing through the thirteenth transistor M13 and the node current ICX flowing through the eleventh transistor M11 in the current comparison circuit 410. The node voltage VCX is coupled to the second terminal of the switch circuit SW, therefore the magnitude of the node current ICX may depend on the node voltage VCX. The lower the node voltage VCX, the larger the node current ICX.

In the current comparison circuit 410, due to the effect of the current mirror structure, the node current ICX also flows through the twelfth transistor M12. Thus, the bias current IBIAS and the node current ICX will pull against each other at the second terminal of the twelfth transistor M12 and thereby change the magnitude of the comparison voltage CMP. In other words, the current comparison circuit 410 may function to compare the node current ICX with the bias current IBIAS. When the node current ICX is smaller than the bias current IBIAS, the comparison voltage CMP will be lower. When the node current ICX is greater than the bias current IBIAS, the comparison voltage CMP will be higher. At time point t0, the comparison voltage CMP is in a voltage corresponding to logic 0.

As shown in FIG. 5, the node voltage VCX will begin to be pulled down from the high voltage value VH at time point t0, the node current ICX increases accordingly, and the comparison voltage CMP also gradually rise. When the activation time Tstr has elapsed and time point t1 is reached, the node voltage VCX is pulled down to a low voltage value VL (indicating that the node voltage VCX has been decreased to the expected voltage), and the comparison voltage CMP rises to the voltage corresponding to logic 1. Therefore, the signal output from the output terminal of the first inverter INV1 is converted to the second logic level, the signal output from the output terminal of the first NAND gate NAND1 is converted to the first logic level, and the control signal GO generated from the output terminal of the third inverter INV3 is converted to the second logic level. Thus, due to the stop of discharge, the node voltage VCX will no longer decrease, and the switch circuit SW in the current comparison circuit 410 will also be turned off as controlled by the control signal GO, no longer generating the bias current IBIAS and the node current ICX, causing the comparison voltage CMP to return to the voltage corresponding to logic 0. The signal output from the output terminal of the first inverter INV1 is therefore converted back to the first logic level.

In summary, the low dropout regulator of the present invention can actively pull down the common mode voltage of the common terminal of the differential input pair, match the voltage between the two sides of the differential input pair (between the two intermediate nodes), to accelerate the discharge speed of the compensation capacitor. As a result, the time spent when activating the low dropout regulator can be significantly reduced, the activation speed can be improved, and the user may use the compensation capacitor with larger capacity, thereby obtaining better stability.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A low dropout regulator, comprising:
an amplifier circuit, operating between a first power supply voltage and a second power supply voltage, comprising a differential input pair having a first stage input circuit and a second stage input circuit, configured to receive an input voltage and a reference voltage through the first stage input circuit and the second stage input circuit, and generate an output voltage according to the input voltage and the reference voltage;
an equalizer circuit, coupled between two intermediate nodes where the first stage input circuit and the second stage input circuit are stacked, configured to short circuit as controlled by a control signal;
a compensation capacitor, coupled to one of the two intermediate nodes;
a discharge circuit, coupled between a common terminal of the differential input pair and the second power supply voltage, configured to pull down a common mode voltage of the common terminal as controlled by the control signal; and
a detection circuit, coupled to the amplifier circuit, the equalizer circuit and the discharge circuit, configured to generate the control signal according to a node voltage of one of the two intermediate nodes.

2. The low dropout regulator as claimed in claim 1, wherein the amplifier circuit converts the input voltage to the output voltage according to the reference voltage.

3. The low dropout regulator as claimed in claim 1, wherein when the control signal is in a first logic level, the equalizer circuit makes a path between the two intermediate nodes conductive.

4. The low dropout regulator as claimed in claim 1, wherein when the control signal is in a first logic level, the discharge circuit pulls down the common mode voltage.

5. The low dropout regulator as claimed in claim 1, wherein the detection circuit determines a duration of an activation time during which the control signal is in a first logic level according to the node voltage.

6. The low dropout regulator as claimed in claim 5, wherein the detection circuit receives a bias voltage, the reference voltage and the node voltage, generates a bias current according to the bias voltage, generates a node current according to the reference voltage and the node voltage, and compares the node current with the bias current to determine the activation time according to a comparison result.

7. The low dropout regulator as claimed in claim 6, wherein when the node current rises to be greater than the bias current, the detection circuit converts the control signal from the first logic level to a second logic level.

8. The low dropout regulator as claimed in claim 6, wherein after the activation time, the equalizer circuit disconnects a path between the two intermediate nodes, the discharge circuit stops pulling down the common mode voltage, thereby allowing the low dropout regulator to recover to its original operation.

9. The low dropout regulator as claimed in claim 6, wherein the detection circuit further receives an enable signal, the detection circuit converts the control signal from a second logic level to the first logic level in response to the enable signal, and begins to generate the bias current and the node current.

10. The low dropout regulator as claimed in claim 1, wherein the two intermediate nodes include a first intermediate node and a second intermediate node, the first stage input circuit comprising:
a first transistor, having a first terminal coupled to a first differential terminal of the differential input pair, a second terminal coupled to the first intermediate node, and a control terminal receiving the reference voltage; and
a second transistor, having a first terminal coupled to a second differential terminal of the differential input pair, a second terminal coupled to the second intermediate node, and a control terminal receiving the input voltage;
wherein the second stage input circuit comprises:
a third transistor, having a first terminal coupled to the first intermediate node, a second terminal coupled to the common terminal, and a control terminal receiving the reference voltage; and
a fourth transistor, having a first terminal coupled to the second intermediate node, a second terminal coupled to the common terminal, and a control terminal receiving the input voltage.

11. The low dropout regulator as claimed in claim 10, wherein a first terminal of the compensation capacitor is coupled to the first intermediate node, and a second terminal of the compensation capacitor receives the output voltage.

12. The low dropout regulator as claimed in claim 1, wherein the amplifier circuit further comprises:
an output buffer stage;
an active load, coupled between the first power supply voltage and two differential terminals of the differential input pair, configured to output a control voltage from one of the two differential terminals to control the output buffer stage, thereby generating the output voltage from the output buffer stage; and
a current source circuit, coupled between the common terminal of the differential input pair and the second power supply voltage, configured to receive an enable signal, and begin to adjust a generated operating current according to a bias voltage in response to the enable signal.

13. The low dropout regulator as claimed in claim 12, wherein the two differential terminals comprises a first differential terminal and a second differential terminal, and the active load comprises:
a fifth transistor, having a first terminal receiving the first power supply voltage, a second terminal coupled to the first differential terminal, and a control terminal coupled to the second differential terminal; and
a sixth transistor, having a first terminal receiving the first power supply voltage, a second terminal coupled to the second differential terminal, and a control terminal coupled to the control terminal of the fifth transistor,
wherein the current source circuit comprises:
a seventh transistor, having a first terminal coupled to the common terminal, and a control terminal receiving the enable signal; and
an eighth transistor, having a first terminal coupled to the second terminal of the seventh transistor, a second terminal receiving the second power supply voltage, and a control terminal receiving the bias voltage,
wherein the output buffer stage comprises:
an output transistor, having a first terminal receiving the first power supply voltage, a second terminal generating the output voltage, and a control terminal receiving the control voltage.

14. The low dropout regulator as claimed in claim 1, wherein the detection circuit comprises:
a current comparison circuit, configured to receive a bias voltage, the reference voltage, the node voltage, the control signal and an enable signal, and generate a bias current according to the bias voltage in response to the control signal and the enable signal, generate a node current according to the reference voltage and the node voltage, and compare the node current with the bias current to generate a comparison voltage;
a rising edge pulse trigger, configured to receive the enable signal, and output a positive pulse signal in response to the enable signal; and
a latch circuit, coupled to the current comparison circuit and the rising edge pulse trigger, configured to receive the comparison voltage and the positive pulse signal, and adjust the control signal according to the comparison voltage and the positive pulse signal.

15. The low dropout regulator as claimed in claim 14, wherein the current comparison circuit comprises:
a ninth transistor, having a first terminal receiving the first power supply voltage, and a control terminal and a second terminal mutually coupled;
a tenth transistor, having a first terminal receiving the first power supply voltage, a second terminal coupled to the second terminal of the ninth transistor, and a control terminal receiving the enable signal;
an eleventh transistor, having a first terminal coupled to the second terminal of the tenth transistor, and a control terminal receiving the reference voltage;
a switch circuit, having a first terminal coupled to the second terminal of the eleventh transistor, a second terminal receiving the node voltage, and a control terminal receiving the control signal to be turned on or turned off as controlled by the control signal;
a twelfth transistor, having a first terminal receiving the first power supply voltage, a second terminal used to generate the comparison voltage, and a control terminal coupled to the control terminal of the ninth transistor; and
a thirteenth transistor, having a first terminal coupled to the second terminal of the twelfth transistor, a second terminal receiving the second power supply voltage, and a control terminal receiving the bias voltage.

16. The low dropout regulator as claimed in claim 14, wherein the latch circuit comprises:
a first inverter, having an input terminal receiving the comparison voltage;
a second inverter, having an input terminal receiving the positive pulse signal;
a first NAND gate, having a first input terminal coupled to an output terminal of the first inverter;
a second NAND gate, having a first input terminal coupled to an output terminal of the first NAND gate, a second input terminal coupled to an output terminal of the second inverter, and an output terminal coupled to a second input terminal of the first NAND gate; and
a third inverter, having an input terminal coupled to the output terminal of the first NAND gate, and an output terminal used to generate the control signal.

17. The low dropout regulator as claimed in claim 14, wherein the node voltage begins to be pulled down from a high voltage value at a first time point, the node current increases accordingly, and the comparison voltage gradually rises, when an activation time has elapsed and a second time point is reached, the node voltage is pulled down to a low voltage value, and the comparison voltage rises to a voltage corresponding to logic 1.
